(19) United States
(12) Patent Application Publication
(10) Pub. No.: US 2013/0221489 A1
(43) Pub. Date: Aug. 29, 2013

(54) INKS AND PROCESSES TO MAKE A CHALCOGEN-CONTAINING SEMICONDUCTOR

(71) Applicants: Yanyan Cao, Wilmington, DE (US); Michael S. Denny, JR., Springfield, PA (US); Lynda Kaye Johnson, Wilmington, DE (US); Meijun Lu, Hockessin, DE (US); Irina Malajovich, Swarthmore, PA (US)

(72) Inventors: Yanyan Cao, Wilmington, DE (US); Michael S. Denny, JR., Springfield, PA (US); Lynda Kaye Johnson, Wilmington, DE (US); Meijun Lu, Hockessin, DE (US); Irina Malajovich, Swarthmore, PA (US)

(73) Assignee: E I DU PONT DE NEMOURS AND COMPANY, Wilmington, DE (US)

(21) Appl. No.: 13/883,293

(22) PCT Filed: Nov. 20, 2011
(86) PCT No.: PCT/US11/61567

§ 371 Date: May 3, 2013

Related U.S. Application Data
(60) Provisional application No. 61/416,013, filed on Nov. 22, 2010.

(51) Int. Cl. H01L 21/02; H01L 29/26

(52) U.S. Cl. CPC H01L 21/02628; H01L 29/26
USPC 257/613; 252/519.4; 438/478

(57) ABSTRACT

The present invention relates to a process to make a chalcogen-containing semiconductor comprising copper, zinc and tin and to inks used in the process. The inks comprise at least one copper, zinc or tin source which is elemental particles of the particular metal.

This application claims the benefit of U.S. Provisional Patent Application No. 61/416,013, filed Nov. 22, 2010 which are herein incorporated by reference.

### FIELD OF THE INVENTION

The present invention relates to a process to make a chalcogen-containing semiconductor comprising copper, zinc and tin.

### BACKGROUND

Thin-film photovoltaic cells typically use semiconductors such as CdTe or copper indium gallium sulfide/selenide (CIGS) as an energy absorber material. Due to the toxicity of cadmium and the limited availability of indium, alternatives are sought. Copper zinc tin sulfide (Cu₂ZnSnS₄ or “CZTS”) possesses a band gap energy of about 1.5 eV and a large absorption coefficient (approx. 10⁴ cm⁻¹), making it a promising CIGS replacement.

The most common approach to fabricate CZTS thin films is to deposit elemental or binary precursors, such as Cu, Zn, Sn, ZnS, and SnS, using a vacuum technique, which is then followed by the chalcogenization of the precursors. The resulting films are continuous deposits which conform to the substrate. However, typical vacuum techniques require complicated equipment and are therefore intrinsically expensive processes.

Low-cost routes to CZTS are available, but have deficiencies. For example, electrochemical deposition to form CZTS is an inexpensive process, but compositional non-uniformity and/or the presence of secondary phases prevents this method from generating high-quality CZTS thin-films. CZTS thin-films can also be made by the spray pyrolysis of a solution containing metal salts, typically CuCl, ZnCl₂, and SnCl₄, using thiourea as the sulfur source. This method tends to yield films of poor morphology, density and grain size. CZTS films formed from oxyhydrate precursors deposited by the sol-gel method also have poor morphology and require an H₂S atmosphere for annealing. Photochemical deposition has also been shown to generate p-type CZTS thin films. However, the composition of the product is not well-controlled, and it is difficult to avoid the formation of impurities such as hydroxides. The synthesis of CZTS films from CZTS nanoparticles, which incorporate high-boiling amines as capping agents, has also been disclosed. The presence of capping agents in the nanoparticle layer can contaminate and lower the density of the annealed CZTS film. A hybrid solution-particle approach to CZTS involving the preparation of a hydrazine-based slurry comprising dissolved Cu—Sn chalcogenides (S or S—Se), Zn-chalcogenide particles, and excess chalcogen has been reported. However, hydrazine is a highly reactive and potentially explosive solvent that is described in the Merck Index as a is “violent poison.”

Mixtures of milled copper, zinc, and tin particles have been used to form CZTS in a complex, multi-step process. This process involves pressing the particle mixture, heating the pressed particles in a vacuum in a sealed tube to form an alloy, melt-spinning to form an alloy strip, mixing the alloy strip with sulfur powder and ball-milling to form a precursor mixture. This mixture can be coated and then annealed under sulfur vapor to form a film of CZTS.

Hence, there still exists a need for simple, low-cost, scalable materials and processes with a low number of operations that provide high-quality, crystalline CZTS films with tunable composition and morphology. There also exists a need for low-temperature, atmospheric-pressure routes to these materials using solvents and reagents with relatively low toxicity.

### BRIEF DESCRIPTION OF THE DRAWINGS AND FIGURES

FIG. 1 shows the XRD pattern of a CZTS thin film from the reaction of copper particles, zinc sulfide particles and tin sulfide particles as described in Example 1.

FIG. 2 shows SEM of the cross section of the CZTS sample obtained in Example 1.

### SUMMARY OF THE INVENTION

One aspect of this invention is an ink comprising in admixture:

a) a vehicle;
b) a copper source selected from the group consisting of: elemental copper-containing particles, copper-containing chalcogenide particles, and mixtures thereof;
c) a zinc source selected from the group consisting of: elemental zinc-containing particles, zinc-containing chalcogenide particles, and mixtures thereof; and
d) a tin source selected from the group consisting of: elemental tin-containing particles, tin-containing chalcogenide particles, and mixtures thereof;
wherein at least one of the copper, zinc or tin sources comprises elemental copper-containing, elemental zinc-containing, or elemental tin-containing particles.

Another aspect of this invention is a process comprising depositing the ink described above on a substrate to form a coated substrate.

Another aspect of this invention is a process comprising:

(a) forming a coated substrate by depositing on a substrate the ink described above: and
(b) heating the coated substrate to provide a film of CZTS/Se, wherein the heating is carried out under an atmosphere comprising an inert gas, and, if the molar ratio of total chalcogen to (Cu+Zn+Sn) in the ink is less than about 1, the atmosphere further comprises a chalcogen source.

Another aspect of this invention is a coated substrate comprising:

a) a substrate; and
b) at least one layer disposed on the substrate comprising in admixture:

i) a copper source selected from the group consisting of: elemental copper-containing particles, copper-containing chalcogenide particles, and mixtures thereof;

ii) a zinc source selected from the group consisting of: elemental zinc-containing particles, zinc-containing chalcogenide particles, and mixtures thereof; and

iii) a tin source selected from the group consisting of: elemental tin-containing particles, tin-containing chalcogenide particles, and mixtures thereof;

wherein at least one of the copper, zinc or tin sources comprises elemental copper-containing, elemental zinc-containing, or elemental tin-containing particles.

### DETAILED DESCRIPTION

Herein, the terms “solar cell” and “photovoltaic cell” are synonymous unless specifically defined otherwise. These terms refer to devices that use semiconductors to convert visible and near-visible light energy into usable electrical energy. The terms “band gap energy,” “optical band gap,” and “band gap” are synonymous unless specifically defined otherwise. These terms refer to the energy required to generate electron-hole pairs in a semiconductor material, which in general is the minimum energy needed to excite an electron from the valence band to the conduction band.

Herein, element groups are represented using CAS notation. As used herein, the term “chalcogen” refers to Group VIA elements, and the terms “metal chalcogenides” or “chalcogenides” refer to materials that comprise metals and Group VIA elements. Suitable Group VIA elements include sulfur, selenium and tellurium. Metal chalcogenides are important candidate materials for photovoltaic applications, since many of these compounds have optical band gap values well within the terrestrial solar spectra.

Herein, the term “binary-metal chalcogenide” refers to a chalcogenide composition comprising one metal. The term “ternary-metal chalcogenide” refers to a chalcogenide composition comprising two metals. The term “quaternary-metal chalcogenide” refers to a chalcogenide composition comprising three metals. The term “multinary-metal chalcogenide” refers to a chalcogenide composition comprising two or more metals, and encompasses ternary and quaternary metal chalcogenide compositions.

Herein, the terms “copper tin sulfide” and “CTS” refer to Cu₂SnS₃. “Copper tin selenide” and “CTSe” refer to Cu₂SnSe₃. “Copper tin sulfide/selenide,” “CTS/Se,” and “CTS-Se” encompass all possible combinations of Cu₂Sn(S,Se)₃, including Cu₂SnS₃, Cu₂SnSe₃, and Cu₂SnSₓSe₃₋ₓ, where 0≦x≦3. The terms “copper tin sulfide,” “copper tin selenide,” “copper tin sulfide/selenide,” “CTS,” “CTSe,” “CTS/Se” and is “CTS-Se” further encompass fractional stoichiometries, e.g., Cu_{1.80}Sn_{1.05}S₃. That is, the stoichiometry of the elements can vary from a strictly 2:1:3 molar ratio. Similarly, the terms “Cu₂S/Se,” “CuS/Se,” “Cu₄Sn(S/Se)₄,” “Sn(S/Se)₂,” “SnS/Se,” and “ZnS/Se” encompass fractional stoichiometries and all possible combinations of Cu₂(S_{y}Se_{1-y}), Cu(S_{y}Se_{1-y}), Cu₄Sn(S_{y}Se_{1-y})₄, Sn(S_{y}Se_{1-y})₂, Sn(S_{y}Se_{1-y}), and Zn(S_{y}Se_{1-y}) from 0≦y≦1.

Herein, the terms “copper zinc tin sulfide” and “CZTS” refer to Cu₂ZnSnS₄. “Copper zinc tin selenide” and “CZTSe” refer to Cu₂ZnSnSe₄. “Copper zinc tin sulfide/selenide,” “CZTS/Se,” and “CZTS-Se” encompass all possible combinations of Cu₂ZnSn(S,Se)₄, including Cu₂ZnSnS₄, Cu₂ZnSnSe₄, and Cu₂ZnSnSₓSe₄₋ₓ, where 0≦x≦4. The terms “CZTS,” “CZTSe,” “CZTS/Se,” and “CZTS-Se” further encompass copper zinc tin sulfide/selenide semiconductors with fractional stoichiometries, e.g., Cu_{1.94}Zn_{0.63}Sn_{1.3}S₄. That is, the stoichiometry of the elements can vary from a strictly 2:1:1:4 molar ratio. Materials designated as CZTS/Se can also contain small amounts of other elements such as sodium. To date, the highest efficiencies have been measured for copper-poor CZTS/Se solar cells, where by “copper-poor” it is understood that the ratio Cu/(Zn+Sn) is less than 1.0. For high efficiency devices, a molar ratio of zinc to tin greater than one is also desirable.

The term “kesterite” is commonly used to refer to materials belonging to the kesterite family of minerals and is also the common name of the mineral CZTS. As used herein, the term “kesterite” refers to crystalline compounds in either the I4- or I4-2m space groups having the nominal formula Cu₂ZnSn(S,Se)₄. It also refers to “atypical kesterites,” wherein zinc has replaced a fraction of the copper, or copper has replaced a fraction of the zinc, to give Cu_{c}Zn_{z}Sn(S,Se)₄, wherein c is greater than two and z is less than one, or c is less than two and z is greater than one. The term “kesterite structure” refers to the structure of these compounds. As used herein, “coherent domain size” refers to the size of crystalline domains over which a defect-free, coherent structure exists. The coherency comes from the fact that the three-dimensional ordering is not is broken inside of these domains.

Herein the terms “nanoparticle,” “nanocrystal,” and “nanocrystalline particle” are synonymous unless specifically defined otherwise, and are meant to include nanoparticles with a variety of shapes that are characterized by an average longest dimension of about 1 nm to about 500 nm. Herein, by nanoparticle “size” or “size range” or “size distribution,” we mean that the average longest dimension of a plurality of nanoparticles falls within the range. “Longest dimension” is defined herein as the measurement of a nanoparticle from end to end. The “longest dimension” of a particle will depend on the shape of the particle. For example, for particles that are roughly or substantially spherical, the longest dimension will be a diameter of the particle. For other particles, the longest dimension is a diagonal or a side.

As defined herein, “coated particles” refers to particles that have a surface coating of organic or inorganic material. Methods for surface-coating inorganic particles are well-known in the art. As defined herein, the terms “surface coating” and “capping agent” are used synonymously and refer to a strongly absorbed or chemically bonded monolayer of organic or inorganic molecules on the surface of the particle(s). In addition to carbon and hydrogen, suitable organic capping agents can comprise functional groups, including nitrogen-, oxygen-, sulfur-, selenium-, and phosphorus-based functional groups. Suitable inorganic capping agents can comprise chalcogenides, including metal chalcogenides, and zintl ions, wherein zintl ions refers to homopolyatomic anions and heteropolyatomic anions that have intermetallic bonds between the same or different metals of the main group, transition metals, lanthanides, and/or actinides.

Elemental and metal chalcogenide particles are composed only of the specified elements or can be doped with small amounts of other elements. As used herein, the term “alloy” refers to a substance that is a mixture, as by fusion, of two or more metals. Throughout the specification, all reference to wt % of particles is meant to include the surface coating. Many suppliers of nanoparticles use undisclosed or proprietary surface is coatings that act as dispersing aids. Throughout the specification, all reference to wt % of particles is meant to include the undisclosed or proprietary coatings that are added by the manufacturer as a dispersant aid. For instance, a commercial copper nanopowder is considered nominally 100 wt % copper.

Herein, by “O-, N-, S-, and Se-based functional groups” is meant univalent groups that comprise O-, N-, S-, or Se-heteroatoms, wherein the free valence is located on this heteroatom. Examples of O-, N-, S-, and Se-based functional groups include alkoxides, amidos, thiolates, and selenolates.

### Ink Compositions

One aspect of this invention is an ink comprising in admixture:

a) a vehicle;
b) a copper source selected from the group consisting of: elemental copper-containing particles, copper-containing chalcogenide particles, and mixtures thereof;
c) a zinc source selected from the group consisting of: elemental zinc-containing particles, zinc-containing chalcogenide particles, and mixtures thereof; and
d) a tin source selected from the group consisting of: elemental tin-containing particles, tin-containing chalcogenide particles, and mixtures thereof;
wherein at least one of the copper, zinc or tin sources comprises elemental copper-containing, elemental zinc-containing, or elemental tin-containing particles.

This ink is referred to as a CZTS/Se precursor ink, as it contains the precursors for forming a CZTS/Se thin film. Preparing the ink typically comprises mixing the components by any conventional method. In some embodiments, the preparation is conducted under an inert atmosphere. In some embodiments, the ink consists essentially of components (a)-(d).

Molar Ratios.

In some embodiments, the molar ratio of Cu:Zn:Sn is about 2:1:1. In some embodiments, the molar ratio of Cu to (Zn+Sn) is less than one. In some embodiments, the molar ratio of Zn to Sn is greater than one. These embodiments are encompassed by the term “a molar ratio of Cu:Zn:Sn is about 2:1:1,” which covers a range of compositions such as Cu:Zn:Sn ratios of 1.75:1:1.35 and 1.78:1:1.26. In some embodiments, the ratio of the Cu, Zn, and Sn can deviate from a 2:1:1 molar ratio by +/−40 mole %, +/−30 mole %, +/−20 mole %, +/−10 mole %, or +/−5 mole %.

Chalcogen Sources.

In some embodiments, at least one of the copper, zinc or tin sources comprises the chalcogenide particles, or the ink further comprises an elemental chalcogen. In some embodiments, the chalcogenide particles are selected from the group consisting of: sulfide particles, selenide particles, sulfide/selenide particles, and mixtures thereof; and the chalcogen is selected from the group consisting of: sulfur, selenium, and mixtures thereof. In some embodiments, the molar ratio of total chalcogen to (Cu+Zn+Sn) is at least about 1. As defined herein, the moles of total chalcogen are determined by multiplying the moles of each chalcogen-containing species by the number of equivalents of chalcogen that it comprises and then summing these quantities. The moles of (Cu+Zn+Sn) are determined by multiplying the moles of each Cu-, or Zn- or Sn-containing species by the number of equivalents of Cu or Zn or Sn that it comprises and then summing these quantities. As defined herein, sources for the total chalcogen include chalcogenide nanoparticles and elemental chalcogen ink components. As an example, the molar ratio of total chalcogen to (Cu+Zn+Sn) for an ink comprising Cu₂S particles, Zn particles, SnS₂ particles and sulfur=[(moles of Cu₂S)+2(moles of SnS₂)+(moles of S)]/[2(moles of Cu₂S)+(moles of Zn)+(moles of SnS₂)].

Vehicle.

The ink comprises a vehicle to carry the particles. In some embodiments, the vehicle is selected from the group consisting of: fluids and low melting solids, wherein the melting point of the low-melting solid is less than about 100° C., 90° C., 80° C., 70° C., 60° C., 50° C., 40° C., or 30° C. In some embodiments, the vehicle comprises solvents. Suitable is solvents include: aromatics, heteroaromatics, alkanes, chlorinated alkanes, ketones, esters, nitriles, amides, amines, thiols, selenols, pyrrolidinones, ethers, thioethers, selenoethers, alcohols, water, and mixtures thereof. Useful examples of these solvents include toluene, p-xylene, mesitylene, benzene, chlorobenzene, dichlorobenzene, trichlorobenzene, pyridine, 2-aminopyridine, 3-aminopyridine, 2,2,4-trimethylpentane, n-octane, n-hexane, n-heptane, n-pentane, cyclohexane, chloroform, dichloromethane, 1,1,1-trichlorethane, 1,1,2-trichloroethane, 1,1,2,2-tetrachloroethane, 2-butanone, acetone, acetophenone, ethyl acetate, acetonitrile, benzonitrile, N,N-dimethylformamide, butylamine, hexylamine, octylamine, 3-methoxypropylamine, 2-methylbutylamine, iso-amylamine, 1-butanethiol, 1-hexanethiol, 1-octanethiol, N-methyl-2-pyrrolidinone, tetrahydrofuran, 2,5-dimethylfuran, diethyl ether, ethylene glycol diethyl ether, diethylsulfide, diethylselenide, 2-methoxyethanol, iso-propanol, butanol, ethanol, methanol and mixtures thereof. In some embodiments, the wt % of the vehicle in the ink is about 98 to about 5 wt %, 90 to 10 wt %, 80 to 20 wt %, 70 to 30 wt %, 60 to 40 wt %, 98 to 50 wt %, 98 to 60 wt %, 98 to 70 wt %, 98 to 75 wt %, 98 to 80 wt %, 98 to 85 wt %, 95 to 75 wt %, 95 to 80 wt %, or 95 to 85 wt %, based upon the total weight of the ink. In some embodiments, the vehicle functions as a dispersant or capping agent, as well as being the carrier vehicle for the particles. Solvent-based vehicles that are particularly useful as capping agents comprise heteroaromatics, amines, thiols, selenols, thioethers, and selenoethers.

Particles.

The particles of the present invention can be purchased or can be synthesized by known techniques, such as milling and sieving of bulk quantities of the material. In some embodiments, the particles have an average longest dimension of less than about 5 microns, 4 microns, 3 microns, 2 microns, 1.5 microns, 1.25 microns, 1.0 micron, or 0.75 micron. In some embodiments, the particles comprise nanoparticles. In some embodiments, the nanoparticles have an average longest dimension of less than about 500 nm, 400 nm, 300 nm, 250 nm, 200 nm, 150 nm, or 100 nm, as determined by electron microscopy. The nanoparticles can is be purchased or can be synthesized by known techniques, such as decomposition and reduction of metal salts and complexes, chemical vapor deposition, electrochemical deposition, use of γ-, x-ray, laser and UV-irradiation, ultrasonic and microwave treatment, electron- and ion-beams, arc discharge, electric explosion of wires, or biosynthesis.

Capping Agent.

In some embodiments, the particles further comprise a capping agent. The capping agent can aid in the dispersion of particles and can also inhibit their interaction and agglomeration in the ink.

In some embodiments, the capping agent comprises a surfactant or a dispersant. Suitable capping agents include:

(a) Organic molecules that contain functional groups such as N-, O-, S-, Se- or P-based functional groups.

(b) Lewis bases. The Lewis base can be chosen such that it has a boiling temperature at ambient pressure that is greater than or equal to about 200° C., 150° C., 120° C., or 100° C. and/or can be selected from the group consisting of: organic amines, phosphine oxides, phosphines, thiols, selenols, and mixtures thereof.

(c) Amines, thiols, selenols, phosphine oxides, phosphines, phosphinic acids, pyrrolidones, pyridines, carboxylates, phosphates, heteroaromatics, peptides, and alcohols.

(d) Alkyl amines, alkyl thiols, alkyl selenols, trialkylphosphine oxide, trialkylphosphines, alkylphosphonic acids, polyvinylpyrrolidone, polycarboxylates, polyphosphates, polyamines, pyridine, alkylpyridines, aminopyridines, peptides comprising cysteine and/or histidine residues, ethanolamines, citrates, thioglycolic acid, oleic acid, and polyethylene glycol.

(e) Inorganic chalcogenides, including metal chalcogenides, and zintl ions.

(f) S²⁻, Se²⁻, Se₂²⁻, Se₃²⁻, Se₄²⁻, Se₆²⁻, Te₂²⁻, Te₃²⁻, Te₄²⁻, Sn₄²⁻, Sn₅²⁻, Sn₉³⁻, Sn₉⁴⁻, SnS₄⁴⁻, SnSe₄⁴⁻, SnTe₄⁴⁻, Sn₂S₆⁴⁻, Sn₂Se₆⁴⁻, Sn₂Te₆⁴⁻, wherein the positively charged counterions can be alkali metal ions, ammonium, is hydrazinium, or tetraalkylammonium.

(g) Degradable capping agents, including dichalcogenocarbamates, monochalcogenocarbamates, xanthates, trithiocarbonates, dichalcogenoimidodiphosphates, thiobiurets, dithiobiurets, chalcogenosemicarbazides, and tetrazoles. In some embodiments, the capping agents can be degraded either by thermal and/or chemical processes, such as acid- and base-catalyzed processes. Degradable capping agents include: dialkyl dithiocarbamates, dialkyl monothiocarbamates, dialkyl diselenocarbamates, dialkyl monoselenocarbamates, alkyl xanthates, alkyl trithiocarbonates, disulfidoimidodiphosphates, diselenoimidodiphosphates, tetraalkyl thiobiurets, tetraalkyl dithiobiurets, thiosemicarbazides, selenosemicarbazides, tetrazole, alkyl tetrazoles, amino-tetrazoles, thio-tetrazoles, and carboxylated tetrazoles. In some embodiments, Lewis bases can be added to nanoparticles stabilized by carbamate, xanthate, or trithiocarbonate capping agents to catalyze their removal from the nanoparticle. The Lewis bases can comprise an amine.

(h) Molecular precursor complexes to copper chalcogenides, zinc chalcogenides, and tin chalcogenides. Suitable ligands for these molecular precursor complexes include: thio groups, seleno groups, thiolates, selenolates, and thermally degradable capping agents, as described above. Suitable thiolates and selenolates include: alkyl thiolates, alkyl selenolates, aryl thiolates, and aryl selenolates.

(i) Molecular precursor complexes to CuS, Cu₂S, ZnS, SnS, SnS₂, Cu₂SnS₃, Cu₂ZnSnS₄.

(j) The solvent in which the particle is formed, such as oleylamine.

(k) Short-chain carboxylic acids, including formic, acetic, and oxalic acid.

Volatile Capping Agents.

In some embodiments, the particles comprise a volatile capping agent. A capping agent is considered volatile if, instead of decomposing and introducing impurities when a composition or ink of nanoparticles is formed into a film, it evaporates during film deposition, drying or annealing. Volatile capping agents include those is having a boiling point less than about 200° C., 150° C., 120° C., or 100° C. at ambient pressure. In some embodiments, volatile capping agents are adsorbed or bonded onto particles during synthesis or during an exchange reaction. Thus, in one embodiment, particles, or an ink or reaction mixture of particles stabilized by a first capping agent, as incorporated during synthesis, are mixed with a second capping agent that has greater volatility to exchange in the particles the second capping agent for the first capping agent. Suitable volatile capping agents include: ammonia, methyl amine, ethyl amine, butylamine, tetramethylethylene diamine, acetonitrile, ethyl acetate, butanol, pyridine, ethanethiol, propanethiol, butanethiol, t-butylthiol, pentanethiol, hexanethiol, tetrahydrofuran, and diethyl ether. Suitable volatile capping agents can also include: amines, amidos, amides, nitriles, isonitriles, cyanates, isocyanates, thiocyanates, isothiocyanates, azides, thiocarbonyls, thiols, thiolates, sulfides, sulfinates, sulfonates, phosphates, phosphines, phosphites, hydroxyls, hydroxides, alcohols, alcoholates, phenols, phenolates, ethers, carbonyls, carboxylates, carboxylic acids, carboxylic acid anhydrides, glycidyls, and mixtures thereof.

Elemental Particles.

In some embodiments, the ink comprises elemental copper-, zinc- or tin-containing particles. Suitable elemental copper-containing particles include: Cu particles, Cu—Sn alloy particles, Cu—Zn alloy particles, and mixtures thereof. Suitable elemental zinc-containing particles include: Zn particles, Cu—Zn alloy particles, Zn—Sn alloy particles, and mixtures thereof. Suitable elemental tin-containing particles include: Sn particles, Cu—Sn alloy particles, Zn—Sn alloy particles, and mixtures thereof. In some embodiments, the elemental copper-, zinc- or tin-containing particles are nanoparticles. Elemental nanoparticles can be obtained commercially from Sigma-Aldrich (St. Louis, Mo.), Nanostructured and Amorphous Materials, Inc. (Houston, Tex.), American Elements (Los Angeles, Calif.), Inframat Advanced Materials LLC (Manchester, Conn.), Xuzhou Jiechuang New Material Technology Co., Ltd. (Guangdong, China), Absolute Co. Ltd. (Volgograd, Russian Federation), is MTI Corporation (Richmond, Va.), or Reade Advanced Materials (Providence, R.I.). Elemental nanoparticles can also be synthesized according to known techniques. In some embodiments, the elemental particles comprise a capping agent.

Chalcomnide Particles.

In some embodiments, the ink comprises copper-, zinc- or tin-containing chalcogenide particles. In some embodiments, the chalcogenide is a sulfide or selenide. Suitable copper-containing chalcogenide particles include: Cu₂S/Se particles, CuS/Se particles, Cu₂Sn(S/Se)₃ particles, Cu₄Sn(S/Se)₄ particles, Cu₂ZnSn(S/Se)₄ particles, and mixtures thereof. Suitable zinc-containing chalcogenide particles include ZnS/Se particles, Cu₂ZnSn(S/Se)₄ particles, and mixtures thereof. Suitable tin-containing chalcogenide particles include: Sn(S/Se)₂ particles, SnS/Se particles, Cu₂Sn(S/Se)₃ particles, Cu₄Sn(S/Se)₄ particles, Cu₂ZnSn(S/Se)₄ particles, and mixtures thereof. In some embodiments, the copper-, zinc-, or tin-containing chalcogenide particles are nanoparticles. Copper-, zinc-, or tin-containing chalcogenide nanoparticles can be purchased commercially from Reade Advanced Materials (Providence, R.I.) or synthesized according to known techniques. A particularly useful method for synthesizing mixtures of copper-, zinc- and tin-containing chalcogenide nanoparticles follows:

A process for synthesizing mixtures comprises:
(a) providing a first aqueous solution comprising two or more metal salts and one or more ligands;
(b) optionally, adding a pH-modifying substance to form a second aqueous solution;
(c) combining the first or second aqueous solution with a chalcogen source to provide a reaction mixture; and
(d) agitating and optionally heating the reaction mixture to produce metal chalcogenide nanoparticles.

In one embodiment, the process further comprises separating the metal chalcogenide nanoparticles from the reaction mixture. In another embodiment, the process further comprises cleaning the surface of the is nanoparticles. In another embodiment, the process further comprises reacting the surface of the nanoparticles with capping groups.

In some instances, the chalcogenide nanoparticles comprise a capping agent. Coated binary, ternary, and quaternary chalcogenide nanoparticles, including CuS, CuSe, ZnS, ZnSe, SnS, Cu₂SnS₃, and Cu₂ZnSnS₄, can be prepared from corresponding metal salts or complexes by reaction of the metal salt or complex with a source of sulfide or selenide in the presence of one or more stabilizing agents at a temperature between 0° C. and 500° C., or between 150° C. and 350° C. In some circumstances, the stabilizing agent also provides the coating. The chalcogenide nanoparticles can be isolated, for example, by precipitation by a non-solvent followed by centrifugation, and can be further purified by washing, or dissolving and re-precipitating. Suitable metal salts and complexes for this synthetic route include Cu(I), Cu(II), Zn(II), Sn(II) and Sn(IV) halides, acetates, nitrates, and 2,4-pentanedionates. Suitable chalcogen sources include elemental sulfur, elemental selenium, Na₂S, Na₂Se, (NH₄)₂S, (NH₄)₂Se, thiourea, and thioacetamide. Suitable stabilizing agents include the capping agents disclosed above. In particular, suitable stabilizing agents include: dodecylamine, tetradecyl amine, hexadecyl amine, octadecyl amine, oleylamine, trioctyl amine, trioctylphosphine oxide, other trialkylphosphine oxides, and trialkylphosphines.

Cu₂S nanoparticles can be synthesized by a solvothermal process, in which the metal salt is dissolved in deionized water. A long-chain alkyl thiol or selenol (e.g., 1-dodecanethiol or 1-dodecaneselenol) can serve as both the sulfur source and a dispersant for nanoparticles. Some additional ligands, including acetate and chloride, can be added in the form of an acid or a salt. The reaction is typically conducted at a temperature between 150° C. and 300° C. and at a pressure between 150 psig and 250 psig nitrogen. After cooling, the product can be isolated from the non-aqueous phase, for example, by precipitation using a non-solvent and filtration.

The chalcogenide nanoparticles can also be synthesized by an is alternative solvothermal process in which the corresponding metal salt is dispersed along with thioacetamide, thiourea, selenoacetamide, selenourea or other source of sulfide or selenide ions and an organic stabilizing agent (e.g., a long-chain alkyl thiol or a long-chain alkyl amine) in a suitable solvent at a temperature between 150° C. and 300° C. The reaction is typically conducted at a pressure between 150 psig nitrogen and 250 psig nitrogen. Suitable metal salts for this synthetic route include Cu(I), Cu(II), Zn(II), Sn(II) and Sn(IV) halides, acetates, nitrates, and 2,4-pentanedionates.

The resultant chalcogenide nanoparticles obtained from any of the three routes are coated with the organic stabilizing agent(s), as can be determined by secondary ion mass spectrometry and nuclear magnetic resonance spectroscopy. The structure of the inorganic crystalline core of the coated binary nanoparticles obtained can be determined by X-ray diffraction (XRD) and transmission electron microscopy (TEM) techniques.

Elemental Chalcogen.

In some embodiments, the ink comprises an elemental chalcogen selected from the group consisting of sulfur, selenium, and mixtures thereof. Useful forms of sulfur and selenium include powders that can be obtained from Sigma-Aldrich (St. Louis, Mo.) and Alfa Aesar (Ward Hill, Mass.). In some embodiments, the chalcogen powder is soluble in the ink vehicle. If the chalcogen is not soluble in the vehicle, its particle size is between 1 nm and 200 microns. In some embodiments, the particles have an average longest dimension of less than about 100 microns, 50 microns, 25 microns, 10 microns, 5 microns, 4 microns, 3 microns, 2 microns, 1.5 microns, 1.25 microns, 1.0 micron, 0.75 micron, 0.5 micron, 0.25 micron, or 0.1 micron. In some embodiments, the chalcogen particles are smaller than the thickness of the film that is to be formed. The chalcogen particles can be formed by ball milling, evaporation-condensation, melting and spraying (“atomization”) to form droplets, or emulsification to form colloids.

Additives.

In some embodiments, the ink comprises up to about 10 wt %, 7.5 wt %, 5 wt %, 2.5 wt % or, 1 wt % of one or more additives selected from the group consisting of: dispersants, surfactants, polymers, binders, is ligands, capping agents, defoamers, thickening agents, corrosion inhibitors, plasticizers, and dopants. Suitable dopants include sodium and alkali-containing compounds selected from the group consisting of: alkali compounds comprising N-, O-, C-, S-, or Se-based organic ligands, alkali sulfides, alkali selenides, and mixtures thereof. Other suitable dopants include antimony chalcogenides selected from the group consisting of: antimony sulfide and antimony selenide. Suitable binders include vinylpyrrolidone/vinylacetate copolymers, including, for example, PVP/VA E-535 (International Specialty Products). In some embodiments, binders function as capping agents. Suitable surfactants comprise siloxy-, fluoryl-, alkyl-, alkynyl-, and ammonium substituted surfactants. These include, for example, Byk® surfactants (Byk Chemie), Zonyl® surfactants (DuPont), Triton® surfactants (Dow), Surfynol® surfactants (Air Products), Dynol® surfactants (Air Products), and Tego® surfactants (Evonik Industries AG). In certain embodiments, surfactants function as capping agents. In some embodiments, the ink comprises one or more binders or surfactants selected from the group consisting of: decomposable binders; decomposable surfactants; cleavable surfactants; surfactants with a boiling point less than about 250° C.; and mixtures thereof. Suitable decomposable binders include: homo- and co-polymers of polyethers; homo- and co-polymers of polylactides; homo- and co-polymers of polycarbonates including, for example, Novomer PPC (Novomer, Inc.); homo- and co-polymers of poly[3-hydroxybutyric acid]; homo- and co-polymers of polymethacrylates; and mixtures thereof. A suitable low-boiling surfactant is Surfynol® 61 surfactant from Air Products. Cleavable surfactants useful herein as capping agents include Diels-Alder adducts, thiirane oxides, sulfones, acetals, ketals, carbonates, and ortho esters. Suitable cleavable surfactants include: alkyl-substituted Diels Alder adducts, Diels Alder adducts of furans; thiirane oxide; alkyl thiirane oxides; aryl thiirane oxides; piperylene sulfone, butadiene sulfone, isoprene sulfone, 2,5-dihydro-3-thiophene carboxylic acid-1,1-dioxide-alkyl esters, alkyl acetals, alkyl ketals, alkyl 1,3-dioxolanes, alkyl 1,3-dioxanes, hydroxylacetals, alkyl glucosides, ether acetals, polyoxyethylene acetals, is alkyl carbonates, ether carbonates, polyoxyethylene carbonates, ortho esters of formates, alkyl ortho esters, ether ortho esters, and polyoxyethylene ortho esters.

Mixtures of Inks.

In some embodiments, two or more inks are prepared. In some embodiments, each ink comprises a complete set of reagents, e.g., each ink comprises at least a zinc source, a copper source, and a tin source. In other embodiments, one ink comprises a complete set of reagents and the other ink(s) comprise a partial set of reagents, e.g., one of the inks comprises copper, zinc and tin sources and a second ink comprises a tin source. The two or more inks can then be combined. This method is especially useful for controlling stoichiometry and obtaining CZTS/Se of high purity. For example, films from different inks can be coated, annealed, and analyzed by XRD prior to mixing. The XRD results can then guide the selection of the type and amount of each ink to be combined. For example, an ink yielding an annealed film of CZTS/Se with traces of copper sulfide and zinc sulfide can be combined with an ink yielding an annealed film of CZTS/Se with traces of tin sulfide, to form an ink that yields an annealed film comprising only CZTS-Se, as determined by XRD. As another example, an ink containing only a tin source can be added in varying amounts to an ink containing copper, zinc and tin sources, and the stoichiometry can be optimized based upon the resulting device performances.

### Processes and Coated Substrates

Another aspect of this invention is a process comprising:

(a) forming a coated substrate by depositing on a substrate an ink comprising in admixture:
i) a vehicle;
ii) a copper source, selected from the group consisting of: elemental copper-containing particles, copper-containing chalcogenide particles, and mixtures thereof;
iii) a zinc source, selected from the group consisting of: elemental is zinc-containing particles, zinc-containing chalcogenide particles, and mixtures thereof; and
iv) a tin source, selected from the group consisting of: elemental tin-containing particles, tin-containing chalcogenide particles, and mixtures thereof;
wherein at least one of the copper, zinc or tin sources comprises elemental copper-containing, elemental zinc-containing, or elemental tin-containing particles; and
   (b) heating the coated substrate to provide a film of CZTS/Se, wherein the heating is carried out under an atmosphere comprising an inert gas, and, if the molar ratio of total chalcogen to (Cu+Zn+Sn) in the ink is less than about 1, the atmosphere further comprises a chalcogen source.

Descriptions and preferences regarding (i)-(iv) are the same as described above for the ink composition. In some embodiments, at least one of the copper, zinc or tin sources comprises copper-containing, zinc-containing, or tin-containing chalcogenide particles, or the ink further comprises an elemental chalcogen; and the molar ratio of total chalcogen to (Cu+Zn+Sn) is at least about 1.

Another aspect of this invention is a coated substrate comprising:

a) a substrate; and
b) at least one layer disposed on the substrate comprising in admixture:

i) a copper source selected from the group consisting of: elemental copper-containing particles, copper-containing chalcogenide particles, and mixtures thereof;

ii) a zinc source selected from the group consisting of: elemental zinc-containing particles, zinc-containing chalcogenide particles, and mixtures thereof; and

iii) a tin source selected from the group consisting of: elemental tin-containing particles, tin-containing chalcogenide particles, and mixtures thereof;

wherein at least one of the copper, zinc or tin sources comprises elemental copper-containing, elemental zinc-containing, or elemental tin-containing particles.

Descriptions and preferences regarding (i)-(iii) are the same as is described above for the ink composition. In some embodiments, the at least one layer of the coated substrate consists essentially of components (i)-(iii).

Substrate.

The substrate can be rigid or flexible. In one embodiment, the substrate comprises: (i) a base; and (ii) optionally, an electrically conductive coating on the base. The base material is selected from the group consisting of glass, metals, ceramics, and polymeric films. Suitable base materials include metal foils, plastics, polymers, metalized plastics, glass, solar glass, low-iron glass, green glass, soda-lime glass, metalized glass, steel, stainless steel, aluminum, ceramics, metal plates, metalized ceramic plates, and metalized polymer plates. In some embodiments, the base material comprises a filled polymer (e.g., a polyimide and an inorganic filler). In some embodiments, the base material comprises a metal (e.g., stainless steel) coated with a thin insulating layer (e.g., alumina).

Suitable electrically conductive coatings include metal conductors, transparent conducting oxides, and organic conductors. Of particular interest are substrates of molybdenum-coated soda-lime glass, molybdenum-coated polyimide films, and molybdenum-coated polyimide films further comprising a thin layer of a sodium compound (e.g., NaF, Na₂S, or Na₂Se).

Ink Deposition.

The ink is disposed on a substrate to provide a coated substrate by solution-based coating or printing techniques, including spin-coating, spray-coating, dip-coating, rod-coating, drop-cast coating, roller-coating, slot-die coating, draw-down coating, ink-jet printing, contact printing, gravure printing, flexographic printing, and screen printing. The coating can be dried by evaporation, by applying vacuum, by heating, or by combinations thereof. In some embodiments, the substrate and disposed ink are heated at a temperature from 80-350° C., 100-300° C., 120-250° C., or 150-190° C. to remove at least a portion of the solvent, if present, by-products, and volatile capping agents. The drying step can be a separate, distinct step, or can occur as the substrate and precursor ink are heated in an annealing step.

Coated Substrate.

In some embodiments, the molar ratio of Cu:Zn:Sn in the coating on the substrate is about is 2:1:1. In other embodiments, the molar ratio of Cu to (Zn+Sn) is less than one. In other embodiments, the molar ratio of Zn:Sn is greater than one. In some embodiments, the particles of the coated substrate are nanoparticles having an average longest dimension of less than about 500 nm, 400 nm, 300 nm, 250 nm, 200 nm, 150 nm, or 100 nm, as determined by electron microscopy. As measured by profilometry, Ra (average roughness) is the arithmetic average deviation of roughness and Wa (average waviness) is the arithmetic average deviation of waviness from the mean line within the assessment length. In some embodiments, the particles are nanoparticles and the Ra of the at least one layer is less than about 1 micron, 0.9 micron, 0.8 micron, 0.7 micron, 0.6 micron, 0.5 micron, 0.4 micron or 0.3 micron, as measured by profilometry. In some embodiments, the Wa of the at least one layer is less than about 1 micron, 0.9 micron, 0.8 micron, 0.7 micron, 0.6 micron, 0.5 micron, 0.4 micron, 0.3 micron, 0.2 micron, or 0.1 micron, as measured by profilometry.

Annealing.

In some embodiments, the process further comprises an annealing step in which the coated substrate is heated at about 100-800° C., 200-800° C., 250-800° C., 300-800° C., 350-800° C., 400-650° C., 450-600° C., 450-550° C., 450-525° C., 100-700° C., 200-650° C., 300-600° C., 350-575° C., or 350-525° C. In some embodiments, the coated substrate is heated for a time in the range of about 1 min to about 48 h; 1 min to about 30 min; 10 min to about 10 h; 15 min to about 5 h; 20 min to about 3 h; or, 30 min to about 2 h. Typically, the annealing comprises thermal processing, rapid thermal processing (RTP), rapid thermal annealing (RTA), pulsed thermal processing (PTP), laser beam exposure, heating via IR lamps, electron beam exposure, pulsed electron beam processing, heating via microwave irradiation, or combinations thereof. Herein, RTP refers to a technology that can be used in place of standard furnaces and involves single-wafer processing, and fast heating and cooling rates. RTA is a subset of RTP, and consists of unique heat treatments for different effects, including activation of dopants, changing is substrate interfaces, densifying and changing states of films, repairing damage, and moving dopants. Rapid thermal anneals are performed using either lamp-based heating, a hot chuck, or a hot plate. PTP involves thermally annealing structures at extremely high power densities for periods of very short duration, resulting, for example, in defect reduction. Similarly, pulsed electron beam processing uses a pulsed high energy electron beam with short pulse duration. Pulsed processing is useful for processing thin films on temperature-sensitive substrates. The duration of the pulse is so short that little energy is transferred to the substrate, leaving it undamaged.

In some embodiments, the annealing is carried out under an atmosphere comprising: an inert gas (nitrogen or a Group VIIIA gas, particularly argon); optionally hydrogen; and optionally, a chalcogen source such as selenium vapor, sulfur vapor, hydrogen sulfide, hydrogen selenide, diethyl selenide, or mixtures thereof. The annealing step can be carried out under an atmosphere comprising an inert gas, provided that the molar ratio of total chalcogen to (Cu+Zn+Sn) in the coating is greater than about 1. If the molar ratio of total chalcogen to (Cu+Zn+Sn) is less than about 1, the annealing step is carried out in an atmosphere comprising an inert gas and a chalcogen source. In some embodiments, at least a portion of the chalcogen present in the coating (e.g., S) can be exchanged (e.g., S can be replaced by Se) by conducting the annealing step in the presence of a different chalcogen (e.g., Se). In some embodiments, annealings are conducted under a combination of atmospheres. For example, a first annealing is carried out under an inert atmosphere and a second annealing is carried out in an atmosphere comprising an inert gas and a chalcogen source as described above or vice versa. In some embodiments, the annealing is conducted with slow heating and/or cooling steps, e.g., temperature ramps and declines of less than about 15° C. per min, 10° C. per min, 5° C. per min, 2° C. per min, or 1° C. per min. In other embodiments, the annealing is conducted with rapid and/or cooling steps, e.g., temperature ramps and declines of greater than about 15° C. per min, 20° C. per min, 30° C. per min, 45° C. per min, or 60 is ° C. per min.

CZTS/Se Composition.

It has been found that CZTS/Se can be formed in high yield during the annealing step, as determined by XRD or XAS. In some embodiments, annealed films consist essentially of CZTS/Se, according to XRD analysis. In some embodiments, the coherent domain size of the CZTS/Se is greater than about 30 nm, or greater than 40, 50, 60, 70, 80, 90 or 100 nm, as determined by XRD. In some embodiments, the molar ratio of Cu:Zn:Sn is about 2:1:1 in the annealed film. In other embodiments, the molar ratio of Cu to (Zn+Sn) is less than one, and, in other embodiments, a molar ratio of Zn to Sn is greater than one in an annealed film comprising CZTS/Se.

Coating and Film Thickness.

By varying the ink concentration and/or coating technique and temperature, layers of varying thickness can be coated in a single coating step. In some embodiments, the coating thickness can be increased by repeating the coating and drying steps. These multiple coatings can be conducted with the same ink or with different inks. As described above, wherein two or more inks are mixed, the coating of multiple layers with different inks can be used to fine-tune stoichiometry and purity of the CZTS/Se films by fine-tuning Cu to Zn to Sn ratios.

The annealed film typically has an increased density and/or reduced thickness versus that of the wet precursor layer. In some embodiments, the film thicknesses of the dried and annealed coatings are 0.1-200 microns; 0.1-100 microns; 0.1-50 microns; 0.1-25 microns; 0.1-10 microns; 0.1-5 microns; 0.1-3 microns; 0.3-3 microns; or 0.5-2 microns.

Purification of Coated Layers and Films.

Application of multiple coatings, washing the coating, and/or exchanging capping agents can serve to reduce carbon-based impurities in the coatings and films. For example, after an initial coating, the coated substrate can be dried and then a second coating can be applied and coated by spin-coating. The spin-coating step can wash organics out of the first coating. Alternatively, is the coated film can be soaked in a solvent and then spun-coated to wash out the organics. Examples of useful solvents for removing organics in the coatings include alcohols, e.g., methanol or ethanol, and hydrocarbons, e.g., toluene. As another example, dip-coating of the substrate into the ink can be alternated with dip-coating of the coated substrate into a solvent bath to remove impurities and capping agents. Removal of non-volatile capping agents from the coating can be further facilitated by exchanging these capping agents with volatile capping agents. For example, the volatile capping agent can be used as the washing solution or as a component in a bath. In some embodiments, a layer of a coated substrate comprising a first capping agent is contacted with a second capping agent, thereby replacing the first capping agent with the second capping agent to form a second coated substrate. Advantages of this method include film densification along with lower levels of carbon-based impurities in the film, particularly if and when it is later annealed. Alternatively, binary sulfides and other impurities can be removed by etching the annealed film using techniques such as those used for CIGS films.

Preparation of Devices, Including Thin-Film Photovoltaic Cells

Various electrical elements can be formed, at least in part, by the use of the inks and processes described herein. One aspect of this invention provides a process for making an electronic device and comprises depositing one or more layers in layered sequence onto the annealed coating of the substrate. The layers can be selected from the group consisting of: conductors, semiconductors, and dielectrics.

Another aspect of this invention provides a process for manufacturing thin-film photovoltaic cells comprising CZTS/Se. A typical photovoltaic cell includes a substrate, a back contact layer (e.g., molybdenum), an absorber layer (also referred to as the first semiconductor layer), a buffer layer (also referred to as the second semiconductor layer), and a top contact layer. The buffer layer, top contact layer, electrode pads and antireflective layer can be deposited onto the is annealed CZTS/Se film. The photovoltaic cell can also include an electrode pad on the top contact layer, and an anti-reflective (AR) coating on the front (light-facing) surface of the substrate to enhance the transmission of light into the semiconductor layer.

In one embodiment, the process provides a photovoltaic device and comprises depositing the following layers in layered sequence onto the annealed coating of the substrate having an electrically conductive layer present: (i) a buffer layer; (ii) a transparent top contact layer, and (iii) optionally, an antireflective layer. In yet another embodiment, the process provides a photovoltaic device and comprises disposing one or more layers selected from the group consisting of buffer layers, top contact layers, electrode pads, and antireflective layers onto the annealed CZTS/Se film. In some embodiments, construction and materials for these layers are analogous to those of a CIGS photovoltaic cell. Suitable substrate materials for the photovoltaic cell substrate are as described above.

### Industrial Utility

Advantages of the inks and processes of the present invention are numerous: 1. The copper, zinc- and tin-containing elemental and chalcogenide particles are easily prepared and, in some cases, commercially available. 2. Combinations of the elemental and chalcogenide particles, particularly nanoparticles, can be prepared that form stable dispersions that can be stored for long periods without settling or agglomeration, while keeping the amount of dispersing agent in the ink at a minimum. 3. The incorporation of elemental particles in the ink can minimize cracks and pinholes in the films and lead to the formation of annealed CZTS films with large grain size. 4. The overall ratios of copper, zinc, tin and chalcogenide in the precursor ink, as well as the sulfur/selenium ratio, can be easily varied to achieve optimum performance of the photovoltaic cell. 5. The use of nanoparticles enables lower annealing temperatures and denser film packing. 6. The ink can be deposited using inexpensive processes. 7. Coatings derived from the ink described herein can be annealed at atmospheric pressure. Moreover, for is certain ink compositions, only an inert atmosphere is required. For other ink compositions, the use of H₂S or H₂Se is not required to form CZTS/Se, since sulfurization or selenization can be achieved with sulfur or selenium vapor.

### EXAMPLES

### General

Materials.

Unless noted otherwise, reagents were purchased from commercial sources and used as received. The surfactant diethylpolypropoxyhydroxyethylammonium is available under the name TEGOO IL P51P from Evonik Industries AG (Essen, Germany). PVP/VA E-535 (International Specialty Products, Wayne, N.J.) is a 50% solution in ethanol of a vinylpyrrolidone/vinylacetate copolymer.

Formulation and Coating Preparations.

Substrates (SLG slides) were cleaned sequentially with aqua regia, Millipore® water and isopropanol, dried at 110° C., and coated on the non-float surface of the SLG substrate. All inks and coatings were prepared in a nitrogen-purged drybox.

Annealing of Coated Substrates in a Tube Furnace.

Annealings were carried out either under a nitrogen, nitrogen/sulfur, or nitrogen/selenium atmosphere. Annealings under a nitrogen atmosphere were carried out in either a single-zone Lindberg/Blue (Ashville, N.C.) tube furnace equipped with an external temperature controller and a one-inch quartz tube, or in a Lindberg/Blue three-zone tube furnace (Model STF55346C) equipped with a three-inch quartz tube. A gas inlet and outlet were located at opposite ends of the tube, and the tube was purged with nitrogen while heating and cooling. The coated substrates were placed on quartz plates inside of the tube.

Annealings under a nitrogen/sulfur atmosphere were carried out in the single-zone furnace in the one-inch tube. A 3-inch long ceramic boat was loaded with 2.5 g of elemental sulfur and placed near the nitrogen inlet, outside of the direct heating zone. The coated substrates were is placed on quartz plates inside the tube. In the following Examples, annealings were carried out under a nitrogen/sulfur atmosphere, unless noted otherwise.

Prior to selenization, samples were first annealed under a nitrogen-purge in the three-inch tube in the three-zone furnace. Then, the samples were placed in a 5″×1.4″×1″ graphite box with ⅛″ walls that was equipped with a lid with a lip and a 1 mm hole in the center. Each graphite box was equipped with two ceramic boats (0.984″×0.591″×0.197″) at each end, containing 0.1 g of selenium. The graphite box was then place in a two-inch tube, with up to two graphite boxes per tube. House vacuum was applied to the tube for 10-15 min, followed by a nitrogen purge for 10-15 min. This process was carried out three times. The tube containing the graphite boxes was then heated in the single-zone furnace with both heating and cooling carried out under a nitrogen purge.

Rapid Thermal Annealing (RTA).

A MILA-5000 Infrared Lamp Heating System by ULVAC-RICO Inc. (Methuen, Mass.) was used for heating and the system was cooled using a Polyscience (Niles, Ill.) recirculating bath held at 15° C. Samples were heated under nitrogen purge as follows: 20° C. for 10 min; ramp to 400° C. in 1 min; hold at 400° C. for 2 min; cool to 20° C. during ˜30 min.

### Details of the Procedures Used for Device Manufacture Mo-Sputtered Substrates.

Substrates for photovoltaic devices were prepared by coating a SLG substrate with a 500 nm layer of patterned molybdenum using a Denton Sputtering System. Deposition conditions were: 150 watts of DC Power, 20 sccm Ar, and 5 mT pressure.

### Cadmium Sulfide Deposition.

12.5 mg Cd50₄ (anhydrous) was dissolved in a mixture of nanopure water (34.95 mL) and 28% NH₄OH (4.05 mL). Then a 1 mL aqueous solution of 22.8 mg thiourea was added rapidly to form the bath solution. Immediately upon mixing, the bath solution was poured into a double-walled beaker (with 70° C. water circulating between the walls), which contained the samples to be coated. The solution was is continuously stirred with a magnetic stir bar. After 23 min, the samples were taken out, rinsed with and then soaked in nanopure water for an hour. The samples were dried under a nitrogen stream and then annealed under a nitrogen atmosphere at 200° C. for 2 min.

### Insulating ZnO and AZO Deposition.

A transparent conductor was sputtered on top of the CdS with the following structure: 50 nm of insulating ZnO (150 W RF, 5 mTorr, 20 sccm) followed by 500 nm of Al-doped ZnO using a 2% Al₂O₃, 98% ZnO target (75 or 150 W RF, 10 mTorr, 20 sccm).

### ITO Transparent Conductor Deposition.

A transparent conductor was sputtered on top of the CdS with the following structure: 50 nm of insulating ZnO [100 W RF, 20 mTorr (19.9 mTorr Ar+0.1 mTorr O₂)] followed by 250 nm of ITO [100 W RF, 12 mTorr (12 mTorr Ar+5×10⁻⁶ Torr O₂)]. The sheet resistivity of the resulting ITO layer is around 30 ohms per square.

### Deposition of Silver Lines.

Silver was deposited at 150 WDC, SmTorr, 20 sccm Ar, with a target thickness of 750 nm.

### Details of X-ray, IV, EQE, and OBIC Analysis.

### XAS Analysis.

XANES spectroscopy at the Cu, Zn and Sn K-edges were carried out at the Advanced Photon Source at the Argonne National Laboratory. Data were collected in fluorescence geometry at beamline 5BMD, DND-CAT. Thin film samples were presented to the incident x-ray beam as made. An Oxford spectroscopy-grade ion chamber was used to determine the X-ray incident intensity (I₀). The I₀ detector was filled with 570 Torr of N₂ and 20 Torr of Ar. The fluorescence detector was a Lytle Cell filled with Xe installed perpendicular to the beam propagation direction. Data were collected from 8879 eV to 9954 eV for the Cu edge. The high final energy was used in order to capture a portion of the Zn edge in the same data set, to allow edge step ratio determination as an estimate of Cu:Zn ratio in the film. The Zn edge data were collected over the range 9557 eV to 10,404 eV. Sn edge data covered the range of 29,000 eV to 29,750 eV. The data energy scales were calibrated based on data from metal reference foils collected prior to sample data collection. A second order background was subtracted and the spectra were normalized. Data from several Cu, Zn and Sn sulfide and oxide standards (Cu₂ZnSnS₄, Cu₂SnS₃, CuS, Cu₂S, CuO, Cu₂O, ZnS, ZnO, SnS, SnO and SnO₂) were obtained under the same conditions. Non-linear least squares fitting of a linear combination of the appropriate standards to the spectra obtained from the samples yielded the phase distribution for each element. XRD Analysis. Powder X-ray diffraction was used for the identification of crystalline phases. Data were obtained with a Philips X′PERT automated powder diffractometer, Model 3040. The diffractometer was equipped with automatic variable anti-scatter and divergence slits, X′Celerator RTMS detector, and Ni filter. The radiation was CuK(alpha) (45 kV, 40 mA). Data were collected at room temperature from 4 to 120°. 2-theta; using a continuous scan with an equivalent step size of 0.02°; and a count time of from 80 sec to 240 sec per step in theta-theta geometry. Thin film samples were presented to the X-ray beam as made. MDI/Jade software version 9.1 was used with the International Committee for Diffraction Data database PDF4+2008 for phase identification and data analysis.

### IV Analysis.

Current (I) versus voltage (V) measurements were performed on the samples using two Agilent 5281B precision medium power SMUs in a E5270B mainframe in a four point probe configuration. Samples were illuminated with an Oriel 81150 solar simulator under 1 sun AM 1.5G.

### EQE Analysis.

External Quantum Efficiency (EQE) determinations were carried out as described in ASTM Standard E1021-06 (“Standard Test Method for Spectral Responsivity Measurements of Photovoltaic Devices”). The reference detector in the apparatus was a pyroelectric radiometer (Laser Probe (Utica, N.Y.), LaserProbe Model RkP-575 controlled by a LaserProbe Model Rm-6600 Universal Radiometer). The excitation light source was a xenon arc lamp with wavelength selection provided by a monochrometer in conjunction with order sorting filters. Optical bias was provided by a broad band tungsten light source focused to a spot slightly larger than the monochromatic probe beam. Measurement spot sizes were approximately 1 mm×2 mm.

### OBIC Analysis.

Optical beam induced current measurements were determined with a purpose-constructed apparatus employing a focused monochromatic laser as the excitation source. The excitation beam was focused to a spot ˜100 microns in diameter. The excitation spot was rastered over the surface of the test sample while simultaneously measuring photocurrent so as to build a map of photocurrent vs position for the sample. The resulting photocurrent map characterizes the photoresponse of the device vs. position. The apparatus can operate at various wavelengths via selection of the excitation laser. Typically, 440, 532 or 633 nm excitation sources were employed.

Synthesis of CuS Nanoparticles.

A solution of copper (II) chloride (1.3445 g, 10 mmol) and trioctylphosphine oxide (11.6 g, 30 mmol) in 40 mL of oleylamine was heated at 220° C. under a nitrogen atmosphere with continuous mechanical stirring for 1 hr, followed by rapid addition of a solution of sulfur (0.3840 g, 12 mmol) in 10 mL of oleylamine. The reaction mixture was maintained at 220° C. for 2 min, and then cooled in an ice-water bath. Hexane (30 mL) was added to the reaction mixture to disperse the nanoparticles. Then, 60 mL of ethanol was added to the mixture to precipitate the nanoparticles. The nanoparticles were collected by centrifuging the mixture and decanting the supernatant, and then the CuS nanoparticles were dried in a vacuum desiccator overnight. The CuS covellite structure was determined by XRD.

Synthesis of Cu Nanoparticles.

A solution of copper nitrate (Cu(NO₃)₂.2.5H₂O, 0.2299 g, 1 mmol), sodium acetate (0.8203 g, 10 mmol), and glacial acetic acid (0.6 mL) in 20 mL of water was mixed with 1-dodecanethiol (3 mL) at room temperature, in a 400 mL glass-lined Hastelloy C shaker tube. The reaction mixture was heated at 200° C. under 250 psig of nitrogen for 6 hr. The reaction mixture was cooled, and the colorless aqueous phase at the bottom of the tube was discarded. Ethanol (20 mL) was added to the dark brown oil phase to precipitate the coated nanoparticles, which were collected via centrifugation. According to XRD and TEM, the coated Cu₂S nanoparticles are roughly spherical, with is an average diameter of 10-15 nm.

Synthesis of SnS Nanoparticles.

A solution of tin(IV) chloride (2.605 g, 10 mmol) and trioctylphosphine oxide (11.6 g, 30 mmol) in 40 mL oleylamine was heated at 220° C. under a nitrogen atmosphere with continuous mechanical stirring for 15 min, followed by rapid addition of a solution of sulfur (0.3840 g, 12 mmol) in 10 mL of oleylamine. The reaction mixture was maintained at 220° C. for 3 min and then cooled in an ice-water bath. Hexane (30 mL) was added to the reaction mixture to disperse the nanoparticles. Then 60 mL of ethanol was added to the mixture to precipitate the nanoparticles. The nanoparticles were collected by centrifuging the mixture and decanting the supernatant, and the SnS nanoparticles were then dried in a vacuum desiccator overnight.

Synthesis of ZnS Nanoparticles.

A solution of ZnCl₂ (3.8164 g, 28 mmol) and trioctylphosphine oxide (32.4786 g, 84 mmol) in 80 mL of oleylamine was heated at 170° C. under a nitrogen atmosphere with continuous mechanical stirring for 1 hr, followed by the rapid addition of a solution of sulfur (0.8960 g, 28 mmol) in 10 mL of oleylamine. The reaction mixture was heated to 320° C. and maintained at this temperature for 75 min, before cooling in an ice-water bath. Hexane (60 mL) was added to the reaction mixture to disperse the nanoparticles. Then, 120 mL of ethanol was added to the mixture to precipitate the nanoparticles. The nanoparticles were collected by centrifuging the mixture and decanting the supernatant, and the ZnS nanoparticles were dried in a vacuum desiccator overnight. The ZnS sphalerite structure was determined by XRD and the size was determined by SEM.

Synthesis of Coated Cu₂SnS₃ Nanoparticles.

A solution of CuCl (0.1980 g, 2 mmol), SnCl₄ (0.2605 g, 1 mmol), and trioctylphosphine oxide (2.3 g, 5.95 mmol) in 10 mL of oleylamine was heated at 240° C. under a nitrogen atmosphere with continuous mechanical stirring for 15 min, followed by the addition of sulfur (0.0960 g, 3 mmol) dissolved in 3 mL of oleylamine. The reaction mixture was stirred at 240° C. for 20 min. The reaction mixture was cooled rapidly by first submerging the reaction vessel in a room temperature water bath and then in an acetone-dry ice bath (−78° C.) to obtain a solid product. The solid was dissolved in hexane and precipitated in ethanol. The precipitated solid was collected using centrifugation. The process of dissolving in hexane, precipitation with ethanol and centrifugation was repeated twice. The Cu₂SnS₃ structure was determined by XRD. Particle shape and size were determined using SEM and TEM. According to SEM, the particles were 10-50 nm in diameter. According to TEM, the particles were 10-30 nm in diameter.

Synthesis of Cu Particles.

Mixed 100 mL aqueous solution of 0.4 M L-ascorbic acid and 0.8 M polyvinylpyrrolidone K30 with 100 mL aqueous solution of 0.025 M copper (II) nitrate hemipentahydrate and 0.8 M polyvinylpyrrolidone K30. Under vigorous magnetic stirring, heated the reaction mixture to 45° C. Continued the reaction at that temperature for 2.5 hr. The nanoparticles were collected by centrifugation and washed with water and then ethanol before drying in vacuum at room temperature.

Removal of the Oxide Layer from Commercial Cu Particles.

Commercial copper nanopowder (99.8%, 1 g, 78 nm, Nanostructured & Amorphous Materials, Inc., Houston, Tex.) was added to a solution containing 10 g citric acid, 1.5 g L-ascorbic acid, 1 mL Citranox (Alconox Inc., White Plains, N.Y.) and 20 mL water. The mixture was sonicated in a bath sonicator at 50° C. for 30 min. The copper nanoparticles were collected by centrifuging and decanting the supernatant. Next, the Cu nanoparticles were washed twice with water and once with ethanol, and then dried in a vacuum desiccator overnight.

### Example 1

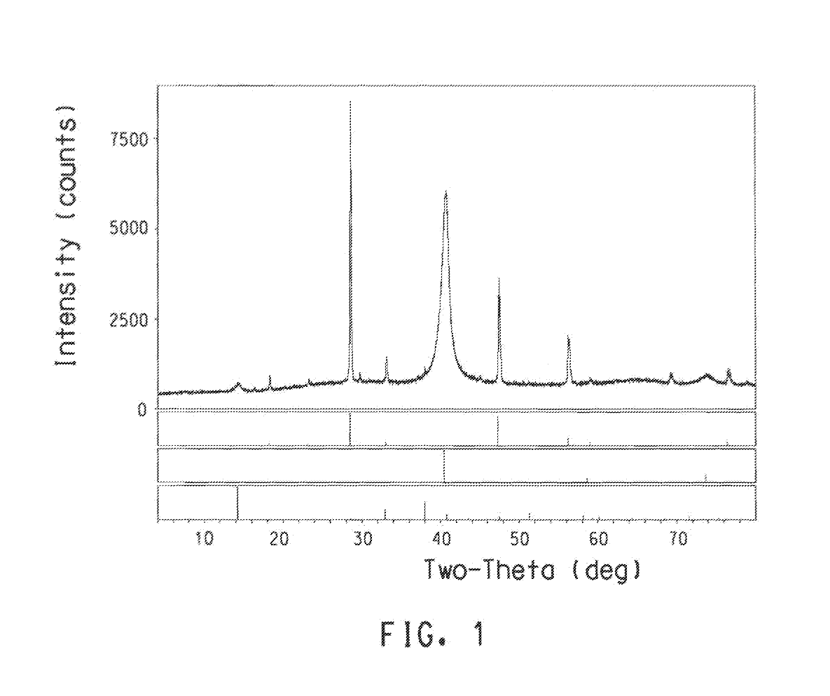

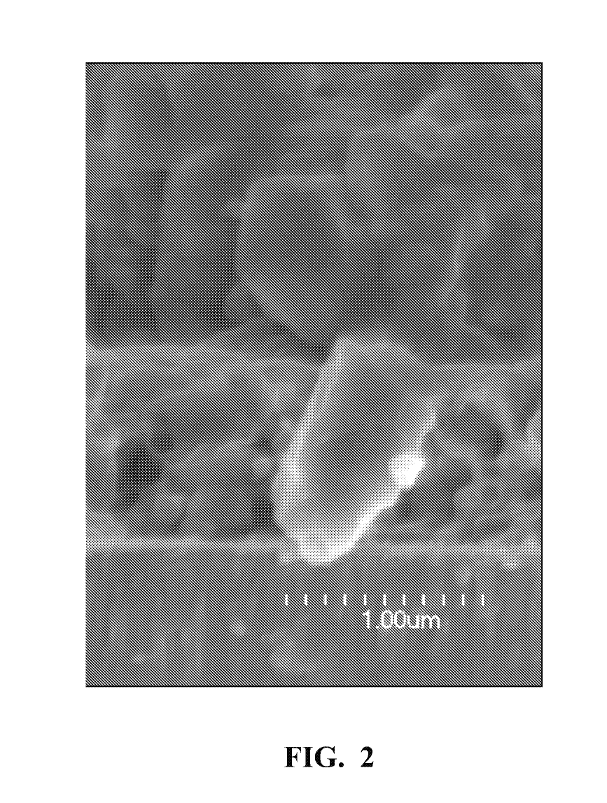

SnS and ZnS nanoparticles (prepared as described above) were individually dispersed in THF at a concentration of 500 mg nanoparticles per mL THF. Each suspension was sonicated in a bath sonicator for 30 min and then with an ultrasonic probe for 10 min. The ZnS suspension was passed through a 1.0 micron syringe filter (Whatman, 1.0 micron GF/B w/GMF). The SnS suspension was passed through a 2.7 micron syringe filter (Whatman, 2.7 micron GF/D w/GMF). Cu nanoparticles (41.9 mg; purified as described above), 0.1540 mL of the ZnS suspension and 0.3460 mL of the SnS suspension were mixed, and the resulting mixture was then sonicated in a bath sonicator for 20 min. This ink was agitated strongly immediately prior to deposition. The ink was spin-coated onto Mo-coated glass substrates by spinning at 1000 rpm for 20 sec and then spinning at 1500 rpm for 10 sec. Then the sample was annealed in a tube furnace at 550° C. for 1 h in N₂ and then at 500° C. for 1 h in a sulfur/N₂ atmosphere. The annealed sample was etched in a 0.5 M KCN solution at 50° C. for 1 min, rinsed with deionized water, and dried under a nitrogen stream. A second etching step was carried out in a 1.0 M HCl solution for 1 min at room temperature, followed by thorough rinsing with deionized water, and drying under a nitrogen stream. XRD results obtained after the annealing step show that the copper, zinc sulfide and tin sulfide precursors were converted to CZTS. The XRD data obtained after heating is shown in FIG. 1. FIG. 2 shows SEM of the cross section of the CZTS sample obtained in Example 1.

### Example 1A

A coated substrate was prepared according to the procedure of Example 1. Profilometry of the surface was acquired in 5 different locations using a Tencor profilometer and the data was processed with a 25 micron low-pass filter, giving an average height of 1.0715 microns, an average Ra of 460 nm, and an average Wa of 231 nm for the coated substrate.

### Example 2

A CZTS precursor ink was prepared by dispersing commercial Sn nanosize activated powder (99.7%, 176.5 mg) from Sigma Aldrich and TEGO IL P51P (10.2 mg) in toluene (2258 mg). The dispersion was then sonicated in an ultrasonic bath for 15 min. Then CuS particles (298.9 mg) and ZnS particles (274.6 mg) were added to the Sn powder suspension. The mixture was further sonicated for 30 min in an ultrasonic bath. The CZTS precursor dispersion was spun-coated onto a molybdenum-coated glass substrate. The ink was applied to the substrate. Then the sample was spun at 200 rpm for 10 sec, followed by spinning at 350 rpm for 30 sec and a final spinning at 600 rpm for 10 sec. The coated substrate was then dried in the air at room temperature. The coated substrate was then annealed in a tube furnace at 500° C. for 2 h in a sulfur/N₂ atmosphere. XRD results indicate that CZTS is the major phase in the annealed film.

### Example 3

A CZTS precursor ink was prepared by dispersing purified Cu particles (61.3 mg), Zn nanopowder (Sigma-Aldrich, 31.5 mg), and Sn nanopowder (Sigma-Aldrich, 57.2 mg) in 0.5 mL PVP/VA E-535 solution in tetrahydrofuran (5% wt.). The dispersion was then sonicated in an ultrasonic bath for 15 min. The CZTS precursor dispersion was spun-coated onto a molybdenum-coated glass substrate. The ink was applied to the substrate. Then the substrate was spun at 1000 rpm for 20 sec, which was followed by spinning at 1500 rpm for 10 sec. The coated substrate was annealed in a tube furnace at 550° C. for 1 h in a N₂ atmosphere. Then it went through a second annealing step in the tube furnace at 500° C. for 1 h in a sulfur/N₂ atmosphere. XRD results confirm the presence of CZTS in the annealed film.

Example 3A. A device was fabricated by following the procedures of Example 3 to provide an annealed CZTS film on a Mo-coated substrate. Cadmium sulfide, insulating ZnO, ITO, and silver lines were deposited. The device efficiency was 0.01%. Analysis by OBIC at 440 nm gave a photoresponse with J90 of 1.3 micro-Amp and dark current of 0.53 micro-Amp. The EQE onset was at 860 nm with an EQE of 0.81% at 640 nm.

### Example 4

A CZTSe precursor ink was prepared by dispersing purified Cu particles (61.3 mg), Zn nanopowder (Sigma-Aldrich, 31.5 mg), and Sn nanopowder (Sigma-Aldrich, 57.2 mg) in 2.5 mL Novomer PPC solution in chloroform (5% wt.). (Novomer high molecular weight poly(propylene carbonate) polyol (Novomer PPC) (advanced ceramics grade) was obtained from Novomer, Inc. (Waltham, Mass.)). The dispersion was then is sonicated in an ultrasonic bath for 15 min. The CZTS precursor dispersion was knife-coated onto a molybdenum-coated glass substrate. The coated substrate was annealed in a tube furnace at 560° C. under argon for 20 min in a graphite box that contained 150 mg selenium and 20 mg tin. XRD results confirmed the presence of CZTSe in the annealed film. SEM images indicated that the selenized films contained some micrometer-sized grains.

What is claimed is:

1. An ink comprising in admixture:
a) a vehicle;
b) a copper source, selected from the group consisting of: elemental copper-containing particles, copper-containing chalcogenide particles, and mixtures thereof;
c) a zinc source, selected from the group consisting of: elemental zinc-containing particles, zinc-containing chalcogenide particles, and mixtures thereof;
d) a tin source, selected from the group consisting of: elemental tin-containing particles, tin-containing chalcogenide particles, and mixtures thereof,
wherein at least one of the copper, zinc or tin sources comprises elemental copper-containing, elemental zinc-containing, or elemental tin-containing particles.

2. The ink of claim 1, wherein a molar ratio of Cu:Zn:Sn is about 2:1:1.

3. The ink of claim 1, wherein at least one of the copper, zinc or tin sources comprises copper-containing, zinc-containing, or tin-containing chalcogenide particles, or the ink further comprises an elemental chalcogen.

4. The ink of claim 3, wherein the chalcogenide particles are selected from the group consisting of: sulfide particles, selenide particles, sulfide/selenide particles, and mixtures thereof; and wherein the elemental chalcogen is sulfur, selenium, or a mixture thereof.

5. The ink of claim 1, wherein the copper source is selected from the group consisting of: Cu particles, Cu—Sn alloy particles, Cu—Zn alloy particles, Cu₂S/Se particles, CuS/Se particles, Cu₂Sn(S/Se)₃ particles, Cu₄Sn(S/Se)₄ particles, Cu₂ZnSn(S/Se)₄ particles, and mixtures thereof; the zinc source is selected from the group consisting of: Zn particles, Cu—Zn alloy particles, Zn—Sn alloy particles, ZnS/Se particles, Cu₂ZnSn(S/Se)₄ particles, and mixtures thereof; and the tin source is selected from the group consisting of: Sn particles, Cu—Sn alloy particles, Zn—Sn alloy particles, Sn(S/Se)₂ particles, SnS/Se particles, Cu₂Sn(S/Se)₃ particles, Cu₄Sn(S/Se)₄ particles, Cu₂ZnSn(S/Se)₄ particles, and mixtures thereof.

6. The ink of claim 1, wherein the copper-, zinc-, or tin-containing chalcogenide particles further comprise an organic capping agent.

7. The ink of claim 1, further comprising up to about 10 wt % of one or more additives selected from the group consisting of: dispersants, is surfactants, polymers, binders, ligands, capping agents, defoamers, thickening agents, corrosion inhibitors, plasticizers and dopants.

8. A process comprising:
(a) forming a coated substrate by depositing on a substrate an ink comprising in admixture:
i) a vehicle;
ii) a copper source, selected from the group consisting of: elemental copper-containing particles, copper-containing chalcogenide particles, and mixtures thereof;
iii) a zinc source, selected from the group consisting of: elemental zinc-containing particles, zinc-containing chalcogenide particles, and mixtures thereof; and
iv) a tin source, selected from the group consisting of: elemental tin-containing particles, tin-containing chalcogenide particles, and mixtures thereof;
wherein at least one of the copper, zinc or tin sources comprises elemental copper-containing, elemental zinc-containing, or elemental tin-containing particles; and
(b) heating the coated substrate to provide a film of CZTS/Se, wherein the heating is carried out under an atmosphere comprising an inert gas, and, if the molar ratio of total chalcogen to (Cu+Zn+Sn) in the ink is less than about 1, the atmosphere further comprises a chalcogen source.

9. The process of claim 8, wherein the atmosphere further comprises hydrogen, a chalcogen source, or mixtures thereof.

10. A coated substrate comprising:
a) a substrate; and
b) at least one layer disposed on the substrate comprising:
i) a copper source, selected from the group consisting of: elemental copper-containing particles, copper-containing chalcogenide particles, and mixtures thereof;
ii) a zinc source, selected from the group consisting of: elemental zinc-containing particles, zinc-containing chalcogenide particles, and mixtures thereof; and
iii) a tin source, selected from the group consisting of: elemental tin-containing particles, tin-containing chalcogenide particles, and mixtures thereof;
wherein at least one of the copper, zinc or tin sources comprises elemental copper-containing, elemental zinc-containing, or elemental tin-containing particles.

11. The coated substrate of claim 10, wherein the molar ratio of Cu:Zn:Sn is about 2:1:1.

12. The coated substrate of claim 10, wherein the copper source is selected from the group consisting of: Cu particles, Cu—Sn alloy particles, Cu—Zn alloy particles, Cu₂S/Se particles, CuS/Se particles, Cu₂Sn(S/Se)₃ particles, Cu₄Sn(S/Se)₄ particles, Cu₂ZnSn(S/Se)₄ particles, and mixtures thereof; the zinc source is selected from the group consisting of: Zn particles, Cu—Zn alloy particles, Zn—Sn alloy particles, ZnS/Se particles, Cu₂ZnSn(S/Se)₄ particles, and mixtures thereof; and the tin source is selected from the group consisting of: Sn particles, Cu—Sn alloy particles, Zn—Sn alloy particles, Sn(S/Se)₂ particles, SnS/Se particles, Cu₂Sn(S/Se)₃ particles, Cu₄Sn(S/Se)₄ particles, Cu₂ZnSn(S/Se)₄ particles, and mixtures thereof.

13. The coated substrate of claim 10, wherein the copper-, zinc- or tin-containing chalcogenide particles comprise an organic capping agent.

14. The coated substrate of claim 10, further comprising up to about 10 wt % of one or more additives selected from the group consisting of: dispersants, surfactants, polymers, binders, ligands, capping agents, defoamers, thickening agents, corrosion inhibitors, plasticizers and dopants.

15. The coated substrate of claim 10, wherein the substrate comprises a material selected from the group consisting of: glass, metals, ceramics, and polymeric films.
